(19) United States
(12) Patent Application Publication
(10) Pub. No.: US 2024/0076774 A1
(43) Pub. Date: Mar. 7, 2024

(54) METHOD FOR CALIBRATING OPTICAL COATING APPARATUSES

(71) Applicant: Carl Zeiss Vision International GmbH, Aalen (DE)

(72) Inventors: Daragh Murphy, Aberfoyle Park (AU); Donald J Rollins, JR., West Fork, AR (US)

(21) Appl. No.: 18/505,861

(22) Filed: Nov. 9, 2023

Related U.S. Application Data
(63) Continuation of application No. PCT/EP2022/062654, filed on May 10, 2022.

(30) Foreign Application Priority Data
May 10, 2021 (WO) PCT/US2021/031520

(51) Int. Cl. C23C 14/54; C23C 16/52

(52) U.S. Cl. CPC C23C 14/547; C23C 16/52

(57) ABSTRACT

A computer-implemented method of generating data for calibrating optical coating apparatuses for applying optical coatings to surfaces of substrates is disclosed. The method includes measuring spectral data of a test coating applied by an optical coating apparatus at a first location; sending a coating data file containing the spectral data to a second location; comparing the measured spectral data of the test coating to target specification data for the test coating; and determining correction factors for correcting deviations to the target specification data for the optical coating apparatus based on the comparison between the measured spectral data and the target specification data; and receiving a target data file containing the correction factors at the first location and calibrating the optical coating apparatus by adjusting an operation parameter of the optical coating apparatus based on the correction factors to correct for deviations from the target specification data.

### CROSS-REFERENCE TO RELATED APPLICATIONS

This application is a continuation application of international patent application PCT/EP2022/062654, filed on May 10, 2022 and designating the U.S., which claims priority to international patent application PCT/US2021/031520, filed on May 10, 2021, both of which are hereby incorporated by reference in their entireties.

### TECHNICAL FIELD

The present disclosure relates to a computer-implemented method and a server configured for generating data for calibrating optical coating apparatuses.

The present disclosure also relates to a computer-implemented method and a server configured for recovering operation of optical coating apparatuses.

### BACKGROUND

Ophthalmic lenses, in particular spectacle lenses, are typically produced in ophthalmic prescription laboratories (e.g., Rx Laboratories) which supply ophthalmic lenses to local businesses, such as opticians, optometrists, wholesalers, and optical chain stores. Typically, an ophthalmic lens, which may be manufactured in a Rx laboratory from an optical substrate, or which may be a mass manufactured stock lens, is transparent in the visible range and can have a protective optical coating which is also transparent in the visible range. Additionally, an ophthalmic lens can be treated with thin film coatings which act as interference filters that can include anti-reflective or specialty reflective coatings, that are usually applied by vacuum deposition by an optical coating apparatus. The ophthalmic lenses are treated with these thin film coatings by means of Physical Vapour Deposition (PVD) which can be ion or plasma assisted. Other methods for applying thin film coatings may also include Chemical Vapour Deposition (CVD).

Optical interference films are used in most optical systems to control or enhance spectral performance. These films are thin layers or blends of optical materials of different refractive indices. When light passes through a change in refractive index, partial reflection occurs. The coherence of these subtle reflections determines the nature of the filter's optical spectrum. Two means of designing and fabricating interference filters are discrete stacks and rugates. Discrete stack filters are alternating layers of optical material. Rugate filters are a continuously graded, periodic blend of two or more optical materials. The mixing ratio of the material blend determines the immediate refractive index of the film.

For example, a sequence of multiple thin film layers is applied to an ophthalmic lens by an optical coating apparatus, where the sequence of layers usually has layers of differing refractive index. In particular, the sequence of layers may have alternating higher and lower refractive indices but are not restricted to this sequence. These layers can be applied to one or both sides of the ophthalmic lens and generally serve the purpose of minimising disruptive reflections or creating specialty coating enhancements such as mirror coats.

Due to deviations in the application of these layers to an ophthalmic lens produced during the manufacturing process, the resulting optical coatings are not always on target or in specification. When the difference between the resulting optical coating achieved is outside the pre-determined tolerances for the respective coating, the ophthalmic lens needs to be either discarded or reworked, which reduces production yields of the Rx laboratory.

The resulting optical coatings on the ophthalmic lens can be analysed by skilled operators within the Rx laboratories at designated time intervals. Alternatively, an external process support provider may perform the analysis. In both scenarios, measured sample optical coatings are compared with design specification parameters to determine whether correction factors are to be applied to the optical coating apparatus to modify subsequent coating depositions to ensure the optical coatings are back within tolerance or specification.

Existing methods of having skilled operators determine and apply correction factors for subsequent application of coatings at designated time intervals is cumbersome and requires that the skilled operators have a good understanding of all the coating processes for the ophthalmic industry. This is particularly cumbersome when any number of different apparatuses can be used in a Rx Laboratory and any number of different coating processes can be installed on the apparatus for different optical substrates.

That is, these skilled operators are required to operate specialised software at each production site to set up and create design files for each coating design for the different ophthalmic lenses. In addition, the skilled operators are required to monitor production processes, determine correction factors and apply the correction factors to the necessary optical coating equipment in the Rx laboratory. This is time consuming and can result in the incorrect use of the software, causing inefficient use of the optical coating apparatus in the Rx laboratory. Also, operators with the appropriate skill level are not always available at the facilities where these optical coatings are applied.

FIG. 1 shows a related art example, which is considered to be the closest related art on which the present disclosure is based, where skilled operators operate specialised software as mentioned above to provide an expert support function 401 to an optical coating apparatus 405 that is configured to apply optical coatings to substrates, at a manufacturing location, when the applied optical coatings are no longer within tolerance or specification.

More specifically, in this related art example, FIG. 1 shows an operator 404 operating an optical coating apparatus 405 that is configured to apply optical coatings to surfaces of spectacle lens substrates. When the applied optical coatings no longer conform to predetermined tolerances, further skilled operators, in the form of experts 100, are required to provide an expert support function 401 to the optical coating apparatus 405 as the operator 404 does not have the appropriate skill level.

To calibrate the optical coating apparatus 405 when the applied optical coatings no longer conforms to predetermined tolerances, the operator 404 further operates a measurement apparatus, in the form of a spectrometer 403, to measure spectral data of a test or sample optical coating. The spectrometer 403 communicates this measured data to a local computer 104 also at the manufacturing location. Software residing on the local computer 402 enables an expert at the manufacturing location to determine the required correction factors to be applied to the optical coating apparatus 405 to bring the subsequent coatings back to specification. Specifically, the local computer 402 communicates the correction factors to the operator 404 for him or her to apply them to the optical coating apparatus 405.

FIGS. 2A to 2D show a flow chart indicative of this related art example in more detail. Here, the local computer 402 implements software for use for single layer and multilayer coating adjustment for an optical coating apparatus 405 that requires calibration by an expert in step 406. As above, the operator operates the optical coating apparatus 405 to apply optical coatings to surfaces of spectacle lens substrates in step 407 and operates the optical coating apparatus 405 to apply a single layer test optical coating to a substrate in step 408. The test optical coating is measured by the operator using a spectrometer 403 in step 409.

The expert, at the manufacturing location, opens 410 software running on the local computer 402, which is configured to receive the spectral measurements, and selects 411 the single layer reference file for the specific coating material being analysed. The expert then browses 412 to the desired wavelength data file location stored at the local computer 402, imports 413 the desired wavelength data file to the software, selects 414 the layer target file in the software, selects 415 the layer material file, and selects 416 the substrate material file. The expert then opens 417 the layer characterisation set up parameters, inputs 418 “best guess” physical thickness upper and lower limits, inputs 419 “best guess” refractive index upper and lower limits, selects 420 the most suitable refractive index dispersion setting, and selects 421 the most suitable extinction setting.

The expert selects 422 calculate result based on these selections and the local computer 402 determines 423 whether the test coating passes relative to the specification for layer thickness. If the local computer 402 determines the answer is NO, the expert defines 424 correction factors for the coating apparatus 405 to adjust for layer thickness and the operator updates 425 the coating apparatus 405 with these correction factors. The operator then applies another single layer test optical coating as per step 408 to determine whether the correction factors have brought the optical coating applied by the coating apparatus 405 back within specification.

If the local computer 402 determines the answer is YES, the local computer 402 then determines 423 whether the test coating passes relative to the specification for refractive index. If the local computer 402 determines the answer is NO, the expert defines 426 further correction factors for the coating apparatus 405 to adjust for refractive index and the operator updates 427 the coating apparatus 405 with these further correction factors. The operator then applies another single layer test optical coating 428 as per step 408 to determine whether the correction factors have brought the optical coating applied by the coating apparatus 405 back within specification.

If the local computer 402 determines the answer is YES, the expert moves 429 onto multilayer adjustment of the coating apparatus 405 if appropriate. Here, the operator operates the optical coating apparatus 405 to apply a multilayer layer test optical coating to a substrate in step 430 and measures the test optical coating using a spectrometer 403 in step 431.

The expert, at the manufacturing location, then opens 432 the software running on the local computer 402, which is configured to receive the spectral measurements, and selects 433 the multilayer reference file for the specific coating being analysed. The expert then browses 434 to the desired wavelength data file location, stored at the local computer 402, imports 435 the desired wavelength data file to the software, selects 436 the design target file in the software, selects 437 the layer material file, and selects 438 the substrate material file. The expert then opens 439 the coating design layer and thickness information, selects 440 the layer or multiple layers to be included in the adjustment, and the determines 441 a percentage change allowed from a target thickness for a layer or multiple layers. The expert then selects 442 calculate the result based on these selections and the local computer 402 determines 443 whether the test coating passes relative to the specification. If the local computer 402 determines the answer is NO, the expert modifies 447 multilayer coating parameters for the coating apparatus 405 by selecting same or alternative layers and then determining same or alternative allowable thickness changes to the respective layers. The operator then applies the parameters to the coating apparatus 405 and applies another multilayer test optical coating as per step 430 to determine whether the parameters have brought the multilayer optical coating applied by the coating apparatus 405 back within specification.

If the local computer 402 determines the answer is YES, the operator runs 444 a production coating cycle on the coating apparatus 405. The operator removes 445 one of the substrates with an applied optical coating from the production coating cycle to be used a test sample and measures 446 the applied optical coating on the spectrometer 403 to determine whether the applied optical coating is within specification for ongoing production monitoring.

This related art example requires the expert to have a good understanding of all of the optical coating processes and be located at the manufacturing location with the optical coating apparatus 105 so as to be able to provide the requisite correction factors to the coating apparatus 105.

In a further related art example, the steps of obtaining measured spectral data of a test coating applied by an optical coating apparatus and determining compliance with a design specification is also disclosed in the related art patent specification U.S. 2007/0202251 A1. U.S. 2007/0202251 A1 discloses analysing optical coatings on ophthalmic lenses using an optical monitor which measures the coating material applied to a special test glass at the same time as a coating is applied to a lens by the optical coating apparatus. As the test coating is measured optically in-situ at the same time as the coating is applied to the lens, the method of U.S. 2007/0202251 A1 can automatically correct for changes in refractive index of layers of the coating and stop the coating of a particular layer of the lens at the precise optical thickness required. The method can also make mirror corrections to subsequent layers of the coating if required based on the measurements.

The method of U.S. 2007/0202251 A1, however, requires the coating apparatus to apply a coating to a special test glass at the same time as applying the coating to the lens and for the test coating to be measured and analysed in situ.

WO2020062016 describes a coating control using forward parameter correction and enhanced reverse engineering. U.S. 2019/0226092 describes a method for forming a layer stack on a substrate by means of a multiplicity of coating processes. An optical spectrum of the layer stack is detected and a correction information is determined based on a mapping function between a deviation of the spectrum from a desired spectrum and a correction information. WO2015099707 describes a method of fabrication of critical layers of integrated computational elements. WO2008152663 describes a machine for controlled deposition of a thin-film multilayer. DE19515172C1 describes a method for depositing colored layers on a substrate.

Thus, there is a need to overcome the deficiencies outlined in the foregoing. The problem underlying the present disclosure therefore consists in there being multiple set up and configuration steps being required to be performed by a skilled operator or expert in situ within each production location and for each optical coating apparatus.

Another problem consists in it being difficult to recover operation of optical coating apparatuses where the optical coating process has been interrupted part way through a production cycle, particularly in production locations where there are no skilled operators.

Before turning to a summary of the present disclosure, it will be appreciated that the discussion of the background to the disclosure is included to explain the context of the disclosure.

### SUMMARY

The problem of there being multiple set up and configuration steps required to be performed by a skilled operator in situ indicated above is solved by a computer-implemented method according to any one of claims 1, 26, and 27 and a server according to any one of independent claims 21, 48, and 49.

The problem of in it being difficult to recover operation of optical coating apparatuses indicated above is solved by a computer-implemented method according to claim 22 and a server according to independent claim 25.

Exemplary embodiments and developments of the disclosure are the subject of the sub-claims.

In one aspect, the present disclosure provides a computer-implemented method of generating data for calibrating optical coating apparatuses configured to apply optical coatings to surfaces of substrates, such as, for example, optical substrates and, in particular, spectacle lens substrates. The method comprises measuring spectral data of a test optical coating having one or more coating layers applied by a coating apparatus at a first location and sending a coating data file containing the spectral data to a second location. The measured spectral data is from e.g., a measurement apparatus, such as a spectrometer, of a test optical coating applied by an optical coating apparatus to a surface of a substrate. Instead of skilled operators of the optical coating apparatuses being required to have an in-depth knowledge of optical coating processes and the actual optical coating apparatus at the manufacturing location to make suitable selections so as to generate an estimated specification of the optical coating intended to be applied, as described above in relation to the closest related art, the method is characterized by comparing, at a second location, the measured spectral data to target specification data for the test optical coating for the optical coating apparatus and determining, at the second location, correction factors for correcting deviations to the target specification data for the optical coating apparatus based on the comparison of the measured spectral data and the target specification data. Moreover, the method includes receiving a target data file containing the correction factors at the first location and calibrating the coating apparatus by adjusting at least one operation parameter of the coating apparatus based on the correction factors to correct for the deviations to the target specification data. Thus, the disadvantages associated with relying on skilled operators being located at the manufacturing location and making “best guess” selections are eliminated to provide a more efficient and accurate computer-implemented method of calibrating optical coating apparatuses. Moreover, this method provides the advantage that at the second location a server and possibly one or more experts may be available for maintaining and/or calibrating multiple optical coating devices located remote from the second location at one or more different first locations.

Further, instead of the optical coating apparatus being configured to apply and measure a coating to a special test glass at the same time as applying the coating to the substrate so that the coating to the substrate can be modified before it is completed, as described above in relation to the related art U.S. 2007/0202251 A1, the method is characterized by comparing the measured spectral data to target specification data for the test optical coating for the optical coating apparatus and determining correction factors for correcting deviations to the target specification data for the optical coating apparatus based on the comparison of the measured spectral data and the target specification data at a remote second location. Thus, U.S. 2007/0202251 A1 is not directed to calibrating an optical coating apparatus as per the method and the disadvantages associated with providing a bespoke optical coating apparatus that can simultaneously apply a coating to a test glass and to a lens are eliminated to provide a more practical computer-implemented method of calibrating optical coating apparatuses.

The measured spectral data which are compared to target specification data as well as the target specification data itself may be received by the computer and/or stored in a memory of the computer, such as a server, located at a second location remote from a first location. The correction factors for the optical coating apparatus to adjust operation parameters of the optical coating apparatus to correct for the deviations to the target specification data may subsequently be output and sent to the coating apparatus located at the first location. The correction factors may e.g., be sent to the first location and/or otherwise output to the optical coating apparatus for immediate application. The term “to output” according to the present disclosure may include various forms of providing the respective information, such as sending, providing for download, uploading in a database and/or any other file administration system, and/or any other form of making the respective information available.

The term “calibrating” means in the context of the present disclosure adjusting optical coating apparatuses precisely for their particular function and in particular to adjust one or more operation parameters of a coating apparatus to be calibrated.

The term “optical coating apparatus” means in the context of the present disclosure an apparatus configured for the application of thin film optical coatings.

The term “apply” means in the context of the present disclosure to deposit or lay.

The term “optical coating” means in the context of the present disclosure a thin film coating consisting of one or more layers of alternating refractive index or gradient refractive index which changes the manner in which a substrate reflects and transmits light.

The term “substrate” means in the context of the present disclosure a base material onto which the optical coating is applied.

The term “surface” means in the context of the present disclosure the convex and concave face or individual face of a substrate.

The term “optical substrate” means in the context of the present disclosure a base material with characteristics relating to the light spectrum onto which an optical coating is applied.

The term “spectral data” means in the context of the present disclosure data relating to or derived from the full wavelength spectrum of light including visible, ultraviolet, and infra-red light.

The term “target specification data” means in the context of the present disclosure data having a specified range of values of the full spectrum of light and required color coordinates for a specified surface of the test optical coating.

The term “test optical coating” means in the context of the present disclosure an optical coating consisting of one or more layers of alternating refractive index applied to a substrate for the purposes of providing spectral data.

The term “correction factor” means in the context of the present disclosure a number by which a given set of parameters are adjusted and calculated to produce new values for the set of parameters.

The term “operation parameter” means in the context of the present disclosure machine settings that determine the outcome of a machine process.

The phrase “deviations to the target specification data” means in the context of the present disclosure differences between the measured spectral data and the specified range of values of spectral data for the test optical coating.

The term “first location” means a location, at which one or more optical coating apparatuses are located, which are or may be calibrated based on data generated at a second location, such as a sever located at a remote second location. In addition, a measurement device for measuring spectral data of a test optical coating may be located at the first location. The first location may be a manufacturing location at which optical coating devices are located for applying optical coatings to surfaces of substrates.

The term “second location” means a location being remote from the first location. The second location may be in communication connection with the first location, for instance via Internet. A server for generating data for calibrating coating apparatuses and/or for recovering operation of optical coating apparatuses may be located at the second location. The second location may be referred to as “server location,” wherein both terms may be used as synonyms. The second location may be a system administration remote location for the remote administration of one or more optical coating devices located at one or more manufacturing locations. Alternatively, the second location may also be remote from the system administration remote location and may be located elsewhere, wherein the server may be accessed remote via Internet as a cloud server.

In an exemplary embodiment, the above method is further characterized by receiving the measured spectral data at a server, wherein the server is configured for implementing the steps of: comparing the measured spectral data to target specification data for the test optical coating for the optical coating apparatus; and determining correction factors for correcting deviations to the target specification data for the optical coating apparatus based on the comparison of the measured spectral data and the target specification data. In addition, the server may be further configured for outputting the correction factors.

In another aspect, the present disclosure provides a server configured for generating data for calibrating optical coating apparatuses configured to apply optical coatings to surfaces of substrates. Instead of skilled operators of the optical coating apparatuses being required to have an in-depth knowledge of optical coating processes and the actual optical coating apparatus at the manufacturing location, as described above in relation to the closest related art, the disclosure provides the server that is configured to: receive measured spectral data of a test optical coating applied by an optical coating apparatus from a measurement apparatus located at a first location and configured to measure spectral data of the test optical coating; compare, at a server location, the measured spectral data to target specification data for the test optical coating for the optical coating apparatus; determine correction factors for correcting deviations to the target specification data for the optical coating apparatus based on the comparison of the measured spectral data and the target specification data; and output/send the correction factors to the optical coating apparatus at the first location to calibrate toe coating apparatus by adjusting at least one operation parameter of the optical coating apparatus based on the correction factors to correct for the deviations to the target specification data. Thus, the disadvantages associated with relying on skilled operators being located at the manufacturing location and making “best guess” selections of the target specification of the coating are eliminated to provide a more efficient and accurate computer-implemented method of calibrating optical coating apparatuses.

Further, as above, instead of the optical coating apparatus being configured to apply and measure a coating to a special test glass at the same time as applying the coating to the substrate so that the coating to the substrate can be modified before it is completed, as described above in relation to the related art U.S. 2007/0202251 A1, the disclosure provides the server that is configured to: receive measured spectral data of a test optical coating applied by an optical coating apparatus from a measurement apparatus configured to measure spectral data of the test optical coating; compare the measured spectral data to target specification data for the test optical coating for the optical coating apparatus; determine correction factors for correcting deviations to the target specification data for the optical coating apparatus based on the comparison of the measured spectral data and the target specification data; and send the correction factors for the optical coating apparatus to the first location to adjust operation parameters of the optical coating apparatus to correct for the deviations to the target specification data. Thus, U.S. 2007/0202251 A1 is not directed to calibrating an optical coating apparatus and the disadvantages associated with providing a bespoke optical coating apparatus that can simultaneously apply a coating to a test glass and to a lens are eliminated to provide a more practical computer-implemented method of calibrating optical coating apparatuses.

The term “server” means in the context of the present disclosure a computer or computers in a network configured to provide services to other computers in the network.

The optical coating apparatuses may reside in ophthalmic prescription laboratories (e.g., Rx Laboratories) which produce and supply ophthalmic lenses. These optical coating apparatuses may apply optical coatings to surfaces of optical substrates in the form of ophthalmic lenses. Examples of optical coatings include anti-reflective thin film coatings, which may be applied by vacuum deposition by the optical coating apparatuses to one or both sides of the ophthalmic lens. The functionality of the method, however, is not limited to anti-reflection treated ophthalmic lenses. The method may also be used for other optical coatings, such as mirror and optical filter coatings.

The term “ophthalmic prescription” means in the context of the present disclosure a set of conditions and constraints applied to an optical substrate to address visual acuity of the wearer.

The method thus provides a way to automatically calculate and deliver correction factors to optical coating apparatuses to adjust their operation parameters to correct for deviations to target specification data. The method therefore improves the accuracy and adherence to the specifications which can thus improve production yields of Rx Laboratories.

The term “target” means in the context of the present disclosure a specified set of requirements for a thin film optical coating or material applied to the surface of the test optical coating.

In an example, the method can be used to automatically calculate and deliver correction factors for the maintenance and quality control of optical coating apparatuses performing thin film coating design sequences for various material single or multiple layer coatings that are applied via vacuum deposition to a substrate such a lens for eyeglasses. The method does so for multiple coating processes on multiple optical coating apparatuses at multiple locations at one time.

In an exemplary embodiment, the measurement apparatus is in data communication with a local computer which is in data communication with the server via a network such as the Internet. Typically, the measurement apparatus is a spectrometer which may also be in data communication with the server. In another exemplary embodiment, the optical coating apparatus is also in data communication with the server and the correction factors are automatically outputted to the optical coating apparatus via the network. Alternatively, human interaction is required to communicate the correction factors to the optical coating apparatus.

The term “local computer” means a computer in a network configured to communicate data to and from a server in the network.

In an exemplary embodiment, the method is further characterized by receiving a coating data file including the measured spectral data and data pertaining to the test optical coating and the optical coating apparatus, and determining the correction factors based on the coating data file and the target specification data.

The phrase “data pertaining to the test optical coating” means in the context of the present disclosure data indicative of features of the test optical coating.

Typically, the coating data file is generated by the local computer from input from a user of the optical coating apparatus.

In an exemplary embodiment, the data pertaining to the optical coating apparatus includes identification data of the optical coating apparatus. For example, a user of the optical coating apparatus selects the particular optical coating apparatus in a user interface running on the local computer to generate the identification data.

The term “user interface” means in the context of the present disclosure software designed to allow the local computer to interact with a user.

In an exemplary embodiment, the test optical coating has one or more layers, and the data pertaining to the test optical coating includes layer data of the one or more layers of the test optical coating from the optical coating apparatus. The layer data may also include layer material data of each of the one or more layers. For example, a user of the optical coating apparatus selects a single layer or multilayer reference file for a specific layer material or multilayer optical coating in the user interface to generate the layer data.

The term “reference file” means in the context of the present disclosure reference data stored in a file format.

In an exemplary embodiment, the data pertaining to the test optical coating further includes surface data of the surface having the test optical coating from the optical coating apparatus. For example, a user of the optical coating apparatus selects the surface type (e.g., convex or concave and or which side of the substrate) having the test optical coating applied in the user interface to generate the surface data.

In an exemplary embodiment, the data pertaining to the test optical coating further includes substrate data of the substrate of the surface having the test optical coating from the optical coating apparatus. For example, a user of the optical coating apparatus selects the substrate material in the user interface to generate the substrate data.

The term “surface data” means in the context of the present disclosure data indicative of the surface of the substrate having the test optical coating.

The term “substrate data” means in the context of the present disclosure data indicative of the substrate having the test optical coating.

In an exemplary embodiment, the method is further characterized by generating the target specification data for the test optical coating for the optical coating apparatus based on the received identification data, layer data, surface data and substrate data.

In an exemplary embodiment, the method is further characterized by generating the target specification data from target files, which may be stored at the server, wherein the target files include data pertaining to each of the optical coating apparatuses and a plurality of optical coating designs to be applied to a plurality of substrates by the optical coating apparatuses.

The term “optical coating designs” means in the context of the present disclosure the structure and positioning of materials of varying refractive index in a layered system.

The term “target files” means target specification data stored in a file format.

In an exemplary embodiment, the data pertaining to the optical coating apparatuses includes tooling factor values of the optical coating apparatus.

The term “tooling factor values” means input parameters that are used to calibrate the physical thickness deposited on a substrate to the set point thickness entered into the optical coating apparatus.

In an exemplary embodiment, the data pertaining to the plurality of optical coating designs includes layer material, refractive index values of the layer material of each the one or more layers, and layer thickness data of each the one or more layers.

Typically, the target specification data includes spectral characteristics of the test optical coating.

The term “spectral characteristics” means in the context of the present disclosure features of the test optical coating relating to the full wavelength spectrum of light.

The target files stored at the server thus obviates the need for the above-mentioned skilled operators to manually input pre-determined material and coating design values and settings from a library of these values and settings into the local computer at each production site to generate the necessary material and coating design values and settings to determine the correction factors. This requires a skill in the art of thin film coatings, which is not required by users of the method. The target files thus form a depository of material values which are pre-configured into a thin film coating design sequence or material single layer process. It is therefore not necessary for the user of the method to access and manipulate these sequences or processes or understand the art of thin film coatings to use the method.

The term “coating design values” means in the context of the present disclosure a set of parameters that are utilized to produce a thin film optical coating.

The term “settings” means in the context of the present disclosure adjustable parameters and specification requirements.

The term “production site” means in the context of the present disclosure a location containing any number of optical coating apparatuses where thin film optical coatings are applied.

The server, in this example, is provided as a web-based platform with each pre-configured thin film coating design sequence and material single layer process being disseminated to any number of optical coating apparatuses at any number of locations so long as network connection is available. The server can thus be used to service any number of optical coating apparatuses at any number of locations concurrently without the need for multiple thin film software packages to be installed on local computers or operators skilled in the art of thin film deposition to be located in each location.

The term “thin film coating design sequence” means in the context of the present disclosure the structure and arrangement of materials in a particular progression that produces an optical coating.

For example, the server is accessed through a host web portal and the user generates at a local computer a coating data file from input from the user and the measured spectral data. The coating data file includes data pertaining to the thin film coating design sequence or material single layer process being analysed on the optical coating apparatus for potential adjustment. The coating data file is uploaded to the server and analysed, and the correction factor for adjustment of the optical coating apparatus is automatically outputted.

In an exemplary embodiment, the method is further characterized by recording the coating data file in association with corresponding correction factors. In addition, the method further includes determining causes for the deviations to the target specification data for the optical coating apparatus based on analysis of the recorded coating data file in association with corresponding correction factors.

The phrase “in association with” means in the context of the present disclosure together with.

In an exemplary embodiment, the method is further characterized by receiving and recording, for example at the server, operating conditions data of the optical coating apparatus when applying the test optical coating, and further determining, for example by the server, causes for the deviations to the target specification data for the optical coating apparatus based on analysis of the operating conditions data.

The method thus can generate and provide information on the performance of an optical coating apparatus, such as a thin film coating apparatus, over time, which in turn allows the user to optimize the apparatus' performance. This further improves the production yields of the Rx laboratory. Moreover, this allows the mining of data to indicate issues with the apparatus, such as process drift, and pre-empt failures.

For example, the server implements a remote software tool that is capable of storing historical data specific to any number of users, having any number of thin film coating apparatuses, having any number of thin film coating processes, for both convex and concave surfaces of the anti-reflection treated ophthalmic lenses. The server also uses algorithms to monitor this data and continually improve accuracy in the analysis results.

In an exemplary embodiment, the method is further characterized by determining a warning when deviations to the target specification data for the optical coating apparatus are detected based on the comparison of the measured spectral data and the target specification data, and outputting the warning.

For example, the method can automatically provide warnings should the respective thin film coating design sequence or material single layer process be out of specification. Also, the method can be configured to provide instructions to the user to contact a person skilled in the art of thin film coatings should the respective thin film coating design sequence or material single layer process be gravely out of specification.

In another aspect, the present disclosure provides a computer-implemented method of recovering operation of optical coating apparatuses configured to apply optical coatings having a plurality of layers to surfaces of substrates. Instead of skilled operators of the optical coating apparatuses being required to have an in-depth knowledge of optical coating processes and the actual optical coating apparatus at the manufacturing location to make suitable selections so as to generate an estimated specification of the optical coating intended to be applied, as described above in relation to the closest related art, the disclosure is characterized by: receiving, at a second location, measured spectral data of an interrupted optical coating comprising one or more deposited layers, including an interrupted layer, from a measurement apparatus located at a first location; comparing, at the second location, the measured spectral data to target specification data for the equivalent layers without interruption of the optical coating for the optical coating apparatus; determining, at the second location, an updated layer thickness for correcting the interrupted layer based on the comparison of the measured spectral data and the target specification data; and sending the updated layer thickness for the optical coating apparatus from the second location to the first location to adjust operation parameters to correct for thickness of the interrupted layer. Thus, the disadvantages associated with relying on skilled operators being located at the manufacturing location and making “best guess” selections are eliminated to provide a more efficient and accurate computer-implemented method of recovering operation of optical coating apparatuses.

Further, instead of the optical coating apparatus being configured to apply and measure a coating to a special test glass at the same time as applying a coating to a substrate so that the coating to the substrate can be modified before it is completed, as described above in relation to the related art U.S. 2007/0202251 A1, the disclosure is characterized by: comparing measured spectral data of an interrupted optical coating comprising one or more deposited layers, including an interrupted layer, to target specification data for the equivalent layers without interruption of the optical coating for the optical coating apparatus; and determining an updated layer thickness for correcting the interrupted layer based on the comparison of the measured spectral data and the target specification data. Thus, the disadvantages associated with providing a bespoke optical coating apparatus that can simultaneously apply a coating to a test glass and to a lens are eliminated to provide a more practical computer-implemented method of recovering operation of optical coating apparatuses.

The measured spectral data which are compared to target specification data as well as the target specification data itself may be received by the computer and/or stored in a memory of the computer. The updated layer thickness for the optical coating apparatus to adjust operation parameters to correct for thickness of the interrupted layer may be output.

In an exemplary embodiment, the method is further characterized by receiving the measured spectral data at a server at the second location, wherein the server is configured for implementing the steps of: comparing measured spectral data of an interrupted optical coating comprising one or more deposited layers, including an interrupted layer, to target specification data for the equivalent layers without interruption of the optical coating for the optical coating apparatus; and determining an updated layer thickness for correcting the interrupted layer based on the comparison of the measured spectral data and the target specification data. In addition, the server may be further configured for outputting the updated layer thickness.

In another aspect, the present disclosure provides a server configured for recovering operation of optical coating apparatuses configured to apply optical coatings having a plurality of layers to surfaces of substrates. Instead of skilled operators of the optical coating apparatuses being required to have an in-depth knowledge of optical coating processes and the actual optical coating apparatus at the manufacturing location, as described above in relation to the closest related art, the disclosure is characterized in that the server is configured to: receive measured spectral data of an interrupted optical coating comprising one or more deposited layers, including an interrupted layer, applied by an optical coating apparatus from a measurement apparatus, the measurement apparatus being located at a first location and configured to measure spectral data of the interrupted optical coating; compare, at the server location, the measured spectral data of the deposited layers, including the interrupted layer, to target specification data for the equivalent layers without interruption of the optical coating for the optical coating apparatus; determine an updated layer thickness for correcting the interrupted layer based on the comparison of the measured spectral data and the target specification data; and output and/or send the updated layer thickness for the optical coating apparatus to the first location to adjust operation parameters to correct for thickness of the interrupted layer. Thus, the disadvantages associated with relying on skilled operators being located at the manufacturing location and making “best guess” selections are eliminated to provide a more efficient and accurate computer-implemented method of recovering operation of optical coating apparatuses.

Further, instead of the optical coating apparatus being configured to apply and measure a coating to a special test glass at the same time as applying the coating to a substrate so that the coating to the substrate can be modified before it is completed, as described above in relation to the related art U.S. 2007/0202251 A1, the disclosure is characterized in that the server is configured to: receive measured spectral data of an interrupted optical coating comprising one or more deposited layers, including an interrupted layer, applied by an optical coating apparatus from a measurement apparatus configured to measure spectral data of the interrupted optical coating; compare the measured spectral data of the deposited layers, including the interrupted layer, to target specification data for the equivalent layers without interruption of the optical coating for the optical coating apparatus; determine an updated layer thickness for correcting the interrupted layer based on the comparison of the measured spectral data and the target specification data; and output the updated layer thickness for the optical coating apparatus to adjust operation parameters to correct for thickness of the interrupted layer. Thus, the disadvantages associated with providing a bespoke optical coating apparatus that can simultaneously apply a coating to a test glass and to a lens are eliminated to provide a more practical computer-implemented method of recovering operation of optical coating apparatuses.

The target specification data, to which the measured spectral data is compared at the second location, may include Cauchy formula coefficients for materials of both low and high index of refraction. Based on the Cauchy formula coefficients the refractive index of optical coating and/or individual layers of the optical coating can be precisely modelled, which may be advantageous for a characterization of the individual layer thicknesses of the optical coating based on the measured spectral data. Hence, this may enhance the comparison of the measured spectral data of the test optical coating and the target specification data and, thus, this may enhance the accuracy of the correction to be determined at the second location.

In another aspect, the present disclosure provides a computer-implemented method of generating data for calibrating optical coating apparatuses configured to apply optical coatings to surfaces of substrates. The method is characterized by measuring spectral data of a test optical coating having one or more coating layers applied by a coating apparatus at a first location; sending a coating data file containing the spectral data to a second location; comparing, at the second location, the measured spectral data of the test optical coating applied by the optical coating apparatus to target specification data for the test optical coating for the optical coating apparatus; determining, at the second location, correction factors for correcting deviations to the target specification data for the optical coating apparatus based on the comparison of the measured spectral data and the target specification data; determining, at the second location, based on information contained in the coating data file an indication of a possible failure of the coating apparatus; sending a target data file containing the correction factors to the first location and calibrating the coating apparatus by adjusting at least one operation parameter of the coating apparatus based on the correction factors to correct for the deviations to the target specification data, and sending to the first location the indication of a possible failure of the coating apparatus. For instance, the possible failure may include a process drift and/or a pre-empt failure. This provides the advantage that a possible faulty operation of the optical coating apparatus to be calibrated can be stopped at a short notice and by this a waste of material otherwise originating a continued faulty operation can be reduced or avoided. Moreover, this provides the advantage that a determination and/or decision whether the optical coating apparatus operates in a possible failure can be made by a server and possibly by support of an expert or expert team at a second location remote from the first location.

Yet another aspect of the disclosure relates to a server configured for generating data for calibrating optical coating apparatuses configured to apply optical coatings to surfaces of substrates, characterized in that the server is configured to receive measured spectral data of a test optical coating applied by an optical coating apparatus from a measurement apparatus located at a first location and configured to measure spectral data of the test optical coating; compare, at a server location, the measured spectral data to target specification data for the test optical coating for the optical coating apparatus; determine correction factors for correcting deviations to the target specification data for the optical coating apparatus based on the comparison of the measured spectral data and the target specification data; determine, at the server location, based on information contained in the coating data file an indication of a possible failure of the coating apparatus; send the correction factors to the optical coating apparatus at the first location to calibrate the coating apparatus by adjusting at least one operation parameter of the optical coating apparatus based on the correction factors to correct for the deviations to the target specification data; and send to the first location the indication of a possible failure of the coating apparatus.

Yet another aspect of the disclosure relates to a computer-implemented method of generating data for calibrating optical coating apparatuses configured to apply optical coatings to surfaces of substrates. The method is characterized by measuring spectral data of a test optical coating having one or more coating layers applied by a coating apparatus at a first location; sending a coating data file containing the spectral data to a second location; comparing, at the second location, the measured spectral data of the test optical coating applied by the optical coating apparatus to target specification data for the test optical coating for the optical coating apparatus; determining, at the second location, correction factors for correcting deviations to the target specification data for the optical coating apparatus based on the comparison of the measured spectral data and the target specification data; and receiving, at the first location, a pass/fail message regarding the measured spectral data meeting the target specification data and a target data file containing the correction factors at the first location and calibrating the coating apparatus by adjusting at least one operation parameter of the coating apparatus based on the correction factors to correct for the deviations to the target specification data. This provides the advantage that information regarding the optical coating is provided, whether the optical coating fulfils predetermined requirements or not. This may allow decision whether the optical coating may be further used or has to be discarded.

Another aspect of the disclosure relates to a server configured for generating data for calibrating optical coating apparatuses configured to apply optical coatings to surfaces of substrates, characterized in that the server is configured to: receive measured spectral data of a test optical coating applied by an optical coating apparatus from a measurement apparatus located at a first location and configured to measure spectral data of the test optical coating; compare, at a server location, the measured spectral data to target specification data for the test optical coating for the optical coating apparatus; determine correction factors for correcting deviations to the target specification data for the optical coating apparatus based on the comparison of the measured spectral data and the target specification data; and send a pass/fail message regarding the measured spectral data meeting the target specification data and the correction factors to the optical coating apparatus at the first location to calibrate the coating apparatus by adjusting at least one operation parameter of the optical coating apparatus based on the correction factors to correct for the deviations to the target specification data.

A pass/fail message is a message indicating, whether the measured spectral data fulfil a predetermined requirement defined in the target specification data and, hence, passes a respective check, or whether the measured spectral data does not fulfil the predetermined requirement and, thus, fails the respective test.

Still another aspect of the disclosure consists in a computer program comprising instructions which, when the program is executed by a computer, cause the computer to carry out the method as described above.

In another aspect the disclosure relates to the following method: A method for manufacturing spectacle lens substrates, the method including a computer-implemented method of generating data for calibrating optical coating apparatuses configured to apply optical coatings to surfaces of spectacle lens substrates, characterized by measuring spectral data of a test optical coating having one or more coating layers applied by an optical coating apparatus at a first location, wherein the first location is a manufacturing location at which optical coating devices are located for applying optical coatings to surfaces of spectacle lens substrates;
sending a coating data file containing the spectral data to a second location, wherein the second location is a system administration remote location for the remote administration of one or more optical coating devices or wherein the second location is remote from the system administration remote location and is accessible remote via Internet as a cloud server;
comparing, at the second location, the measured spectral data of the test optical coating applied by the optical coating apparatus to target specification data for the test optical coating for the optical coating apparatus;
determining, at the second location, correction factors for correcting deviations to the target specification data for the optical coating apparatus based on the comparison of the measured spectral data and the target specification data; and
receiving a target data file containing the correction factors at the first location and calibrating the optical coating apparatus by adjusting at least one operation parameter of the optical coating apparatus based on the correction factors to correct for the deviations to the target specification data.

### BRIEF DESCRIPTION OF DRAWINGS

Exemplary embodiments of the present disclosure will now be described, by way of example only, with reference to the accompanying drawings, in which:

FIG. 1 is a block diagram of a related art example of skilled operators providing an expert support function to an optical coating apparatus at a manufacturing location;

FIGS. 2A to 2D show a flow chart of a related art example of skilled operators providing an expert support function to an optical coating apparatus at a manufacturing location;

FIG. 3 is a block diagram of a system including a server according to an exemplary embodiment of the present disclosure;

FIG. 4 is a flow chart of an exemplary embodiment of a method of the present disclosure;

FIG. 5 is a flow chart of an exemplary embodiment of a method of the present disclosure;

FIG. 6A is a flow chart of an exemplary embodiment of a method of the present disclosure;

FIG. 6B is a continuation of the flow chart of FIG. 6A;

FIG. 7A is a continuation of the flow chart of FIG. 6B;

FIG. 7B is a continuation of the flow chart of FIG. 7A;

FIG. 8 is a flow chart of an exemplary embodiment of a method of the present disclosure; and

FIG. 9 is a flow chart of an exemplary embodiment of a method of the present disclosure.

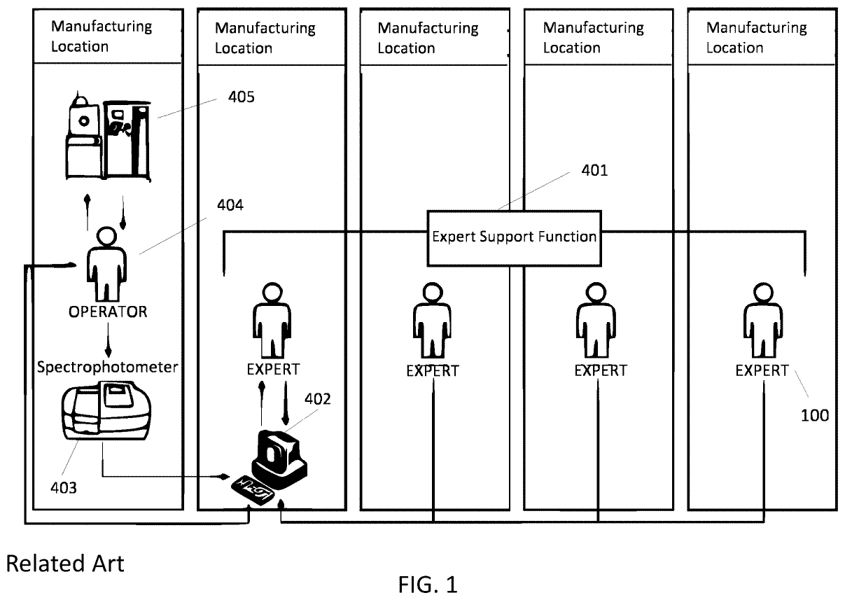

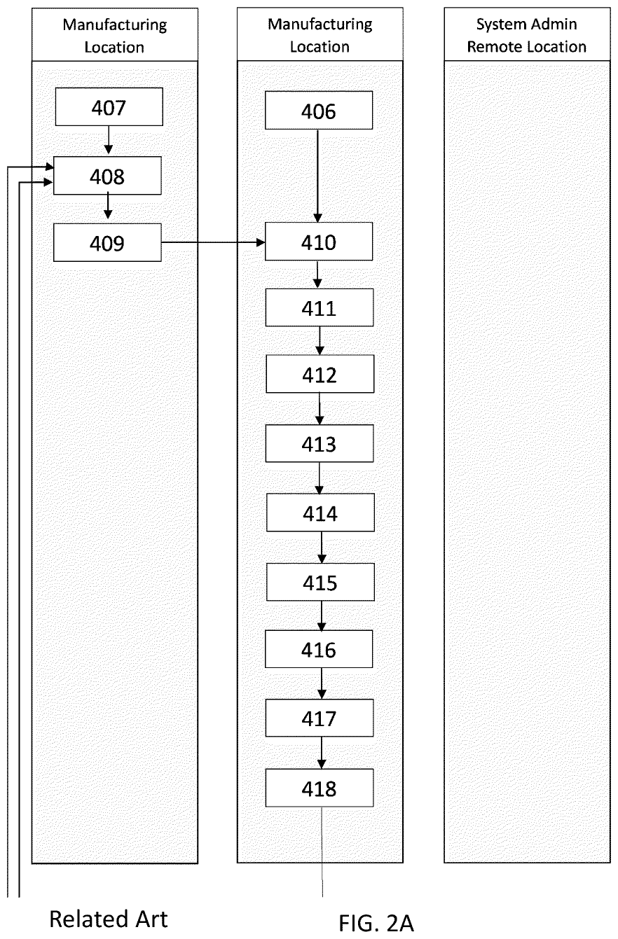

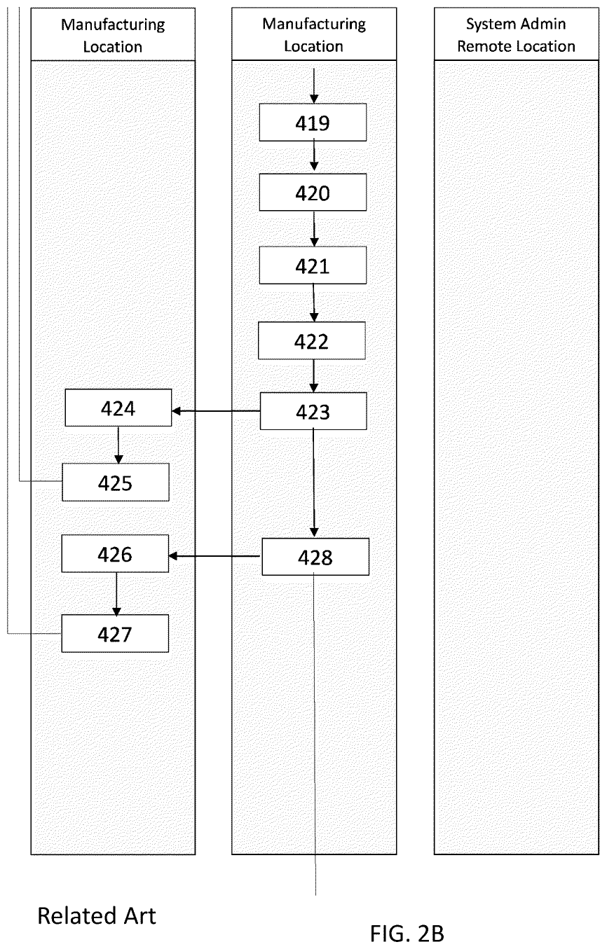

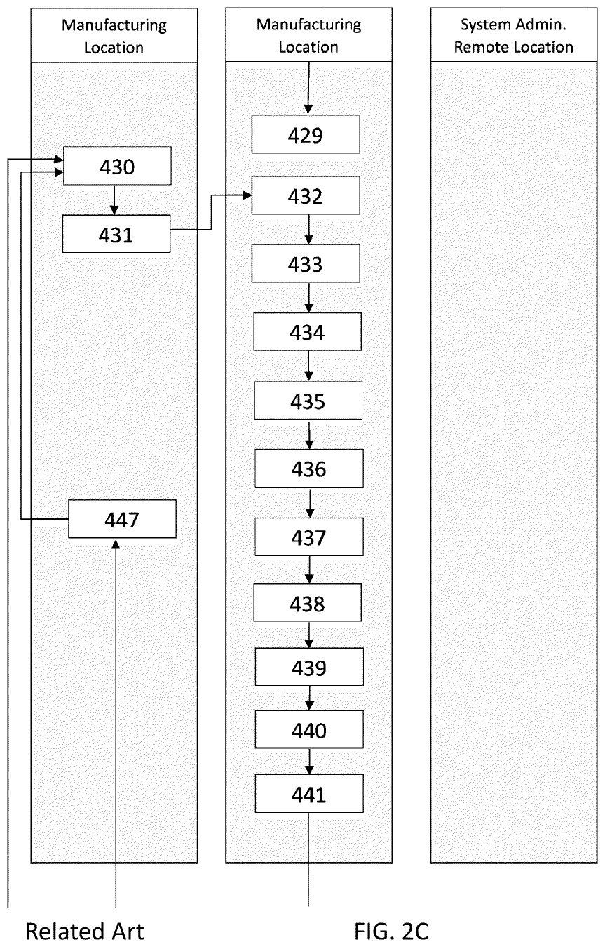

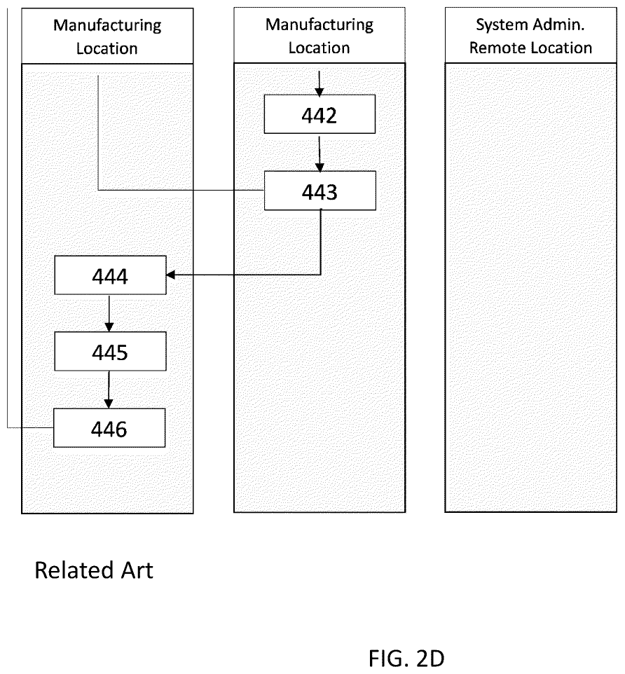

### DESCRIPTION OF EXEMPLARY EMBODIMENTS

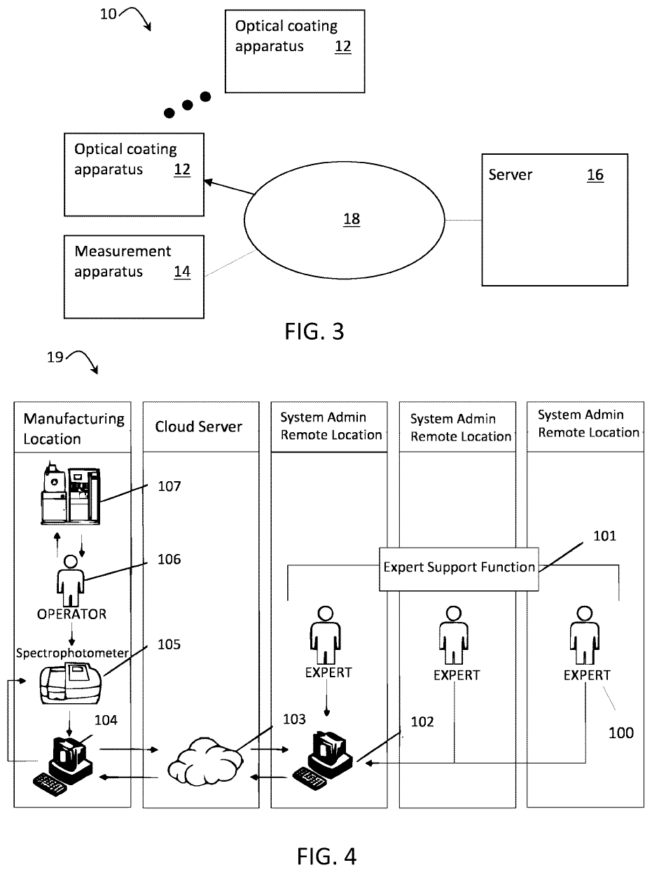

FIG. 3 shows an exemplary embodiment of a system 10 including a plurality of optical coating apparatuses 12 configured to apply optical coatings to surfaces of spectacle lens substrates, a measurement apparatus 14 configured to measure spectral data of the test optical coating, and a server 16 configured for generating data for calibrating the optical coating apparatuses 12. It will be appreciated by those person skilled in the art that the optical coating apparatuses 12 are located in laboratories at one or more first locations, such as Rx laboratories, as described above, and each laboratory has an associated measurement apparatus 14.

As mentioned above, the server 16 is configured to separate and automate activities previously conducted by skilled operators of the optical coating apparatuses 12. Users of the system 10 are required to obtain measured spectral data of a test optical coating applied by an optical coating apparatus 12 using an associated measurement apparatus 14. The users can then use an associated local computer (not shown), in data communication with the server 16, to transmit the measured spectral data from the first location to the server 16 at the second location over the Internet 18.

The server 16 is located at a second location remote from the first location and configured to receive the measured spectral data of a test optical coating applied by the optical coating apparatus 12 from the measurement apparatus 14 from the local computer and to compare the measured spectral data to target specification data for the test optical coating for the optical coating apparatus 12.

The server 16 is further configured to determine correction factors for correcting deviations to the target specification data for the optical coating apparatus 12 based on the comparison of the measured spectral data and the target specification data, and to output the correction factors for the optical coating apparatus 12 to the local computer for the user to adjust operation parameters of the optical coating apparatus 12 to correct for the deviations to the target specification data.

The server 16 is further configured to determine correction factors for correcting deviations to the target specification data for the optical coating apparatus 12 based on the comparison of the measured spectral data and the target specification data, and to output the correction factors for the optical coating apparatus 12 to the local computer for the user to adjust operation parameters of the optical coating apparatus 12 to correct for the deviations to the target specification data.

The server 16 can also be configured for recovering operation of the optical coating apparatuses 12, where the apparatuses are configured to apply optical coatings having a plurality of layers to surfaces of optical substrates. In this exemplary embodiment, the server 16 is configured to receive measured spectral data of an interrupted optical coating comprising one or more deposited layers, including an interrupted layer, applied by the optical coating apparatus 12 from the associated measurement apparatus that is also configured to measure spectral data of interrupted optical coatings.

The server 16 is further configured to compare the measured spectral data for the deposited layers, including for the interrupted layer of the interrupted optical coating for the optical coating apparatus 12, to the target specification data for the equivalent uninterrupted layers.

The server 16 is further configured to determine an updated layer thickness for correcting the interrupted layer based on the comparison of the measured spectral data and the target specification data, and to output the updated layer thickness for the optical coating apparatus 12 to adjust operation parameters to correct for thickness of the interrupted layer.

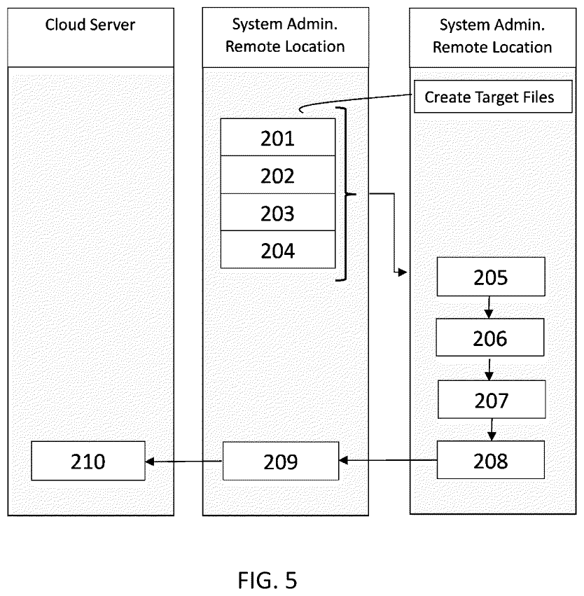

FIG. 4 shows a flow chart of the user, shown as operator 106, using a system 19 to generate data to calibrate an optical coating apparatus 107 using a system administration server 102 according to an exemplary embodiment of the present disclosure. The operator 106 accesses the system administration server 102 via a cloud server 103 and software residing on a local computer 104.

The software residing on the local computer 104 provides a user interface for appropriate optical coating apparatus and optical coatings selections to be made. The operator 106 obtains measured spectral data from a spectrophotometer 105 of a test optical coating applied by the optical coating apparatus 107. The software resident on the local computer 104 provides a coating data file including the measured spectral data and data pertaining to the test optical coating and the optical coating apparatus selected by the operator 106 to be uploaded to the system administration server 102. The system administration server 102 then determines the correction factors based on the coating data file and the target specification data. The local computer 104 receives these correction factors from the system administration server 102 along with any follow up instructions to the user.

FIG. 4 also shows an expert 100 of the system 19 creating the target specification data for the system administration server 102 to use in determining the correction factors. The system 10 is a distributed computing system, where a plurality of manufacturing sites can communicate with the system administration server 102. The expert support function 101 is also a remote function. That is, multiple remote experts, having the necessary knowledge in the art of thin film coatings, can create the required target specification data in the form of design files.

For example, a user of the system 10, shown as operator 106, manufactures a material single layer or thin film coating of a plurality of alternating low and high refractive index materials using an optical coating apparatus 107. The user measures the manufactured item using the spectrophotometer 105, or similar measurement device, and provides a coating data file including the measured spectral data forming a production run file to the distributed computing server 102 103. The distributed computing server 102 103 thereby calculates and automatically returns to the local computing device 104 correction factors (or adjustment factors) to be inputted by the operator 106 to the thin optical coating apparatus 107 to correct for deviations to the target specification data.

The pre-configuration of the distributed computing server system 102 103 is shown in the flow chart of FIG. 5. Here, the expert support function 101 creates the target specification data which includes single layer target files 201, which may comprise of detail such as, but not limited to, spectral wavelength data, for materials of both low and high index of spectral characteristics such as Cauchy formula coefficients, refractive index values, unit allocation, physical thickness of layers, color coordinate allocation, for materials such as but not limited to Cr₂O₃, SiO₂, ZrO₂, ZrO, Ti₃O₅, TiO₂, Al₂O₃, MgF₂, ZnO, ZnS, MgO, Ta₂O₅, HfO₂, Nb₂O₅, Indium Tin Oxide, as well as mixtures of these materials and/or hyper- or sub-stoichiometric variations of these materials.

The target specification data further includes thin file coating design target files (for example, optical coating design target files) 202, created by the expert support function 101, which may comprise of detail such as, but not limited to, spectral wavelength data, for materials of both low and high index of spectral characteristics such as Cauchy formula coefficients, refractive index values and unit allocation.

The expert support function 101 further creates the substrate files 203 for the target specification data, which may comprise of details such as, but not limited to, Cauchy formula coefficients, refractive index values, unit allocation, substrate material type and composition.

The expert support function 101 further creates the thin film optical coating color target values 204 for the target specification data, which may comprise of details such as, but not limited to, refractive index values, unit allocation, limit allocation and color coordinate values. The color coordinate values may be represented, but not limited to representation using coordinate values such as L*, a*, b*, CIE xyz (1931), CIE UCS (1976), CIE C*hs (UV), CIE H° LC & CRI.

In addition, the expert support function 101 generates and configures Single Layer reference files 205 for the target specification data using the target files 201 202 203 204, for each of the materials, but not limited to Cr₂O₃, SiO₂, ZrO₂, ZrO, Ti₃O₅, TiO₂, Al₂O₃, MgF₂, ZnO, ZnS, MgO, Ta₂O₅, HfO₂, Nb₂O₅, Indium Tin Oxide as well as mixtures of these materials and/or hyper- or sub-stoichiometric variations of these materials.

After the Single Layer Reference Files 205 are created, the server is now ready for use for single layer adjustment and set up of Multilayer Reference Files 206. The expert support function 101 generates the multilayer reference files 207 for the target specification data from each of the Target files 201 202 203 204 for each thin film optical coating of a plurality of different refractive index materials (for example, an anti-reflective optical coating would usually have alternating low and high refractive index materials). These layers may consist of, but are not limited to, Cr₂O₃, SiO₂, ZrO₂, ZrO, Ti₃O₅, TiO₂, Al₂O₃, MgF₂, ZnO, ZnS, MgO, Ta₂O₅, HfO₂, Nb₂O₅, and Indium Tin Oxide, as well as mixtures of these materials and/or hyper- or sub-stoichiometric variations of these materials, refractive index values, Cauchy formula coefficients, unit allocation, limit allocation, color coordinate values.

After generating and transmitting 208 these files, the server system 102 103 is now ready for configuration of single layer and multilayer adjustment in step 209. That is, the expert support function 101 configures the server system 102 103 for the operator 106 to be able to select the appropriate single layer files and multilayer thin film process designs to create the appropriate target specification data for the server system 102 103 to determine and output 210 the correction factors.

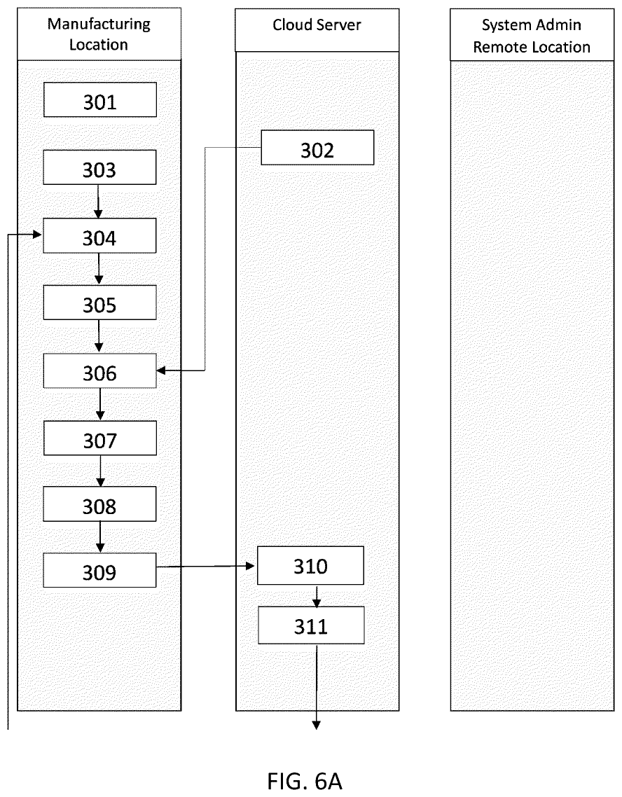

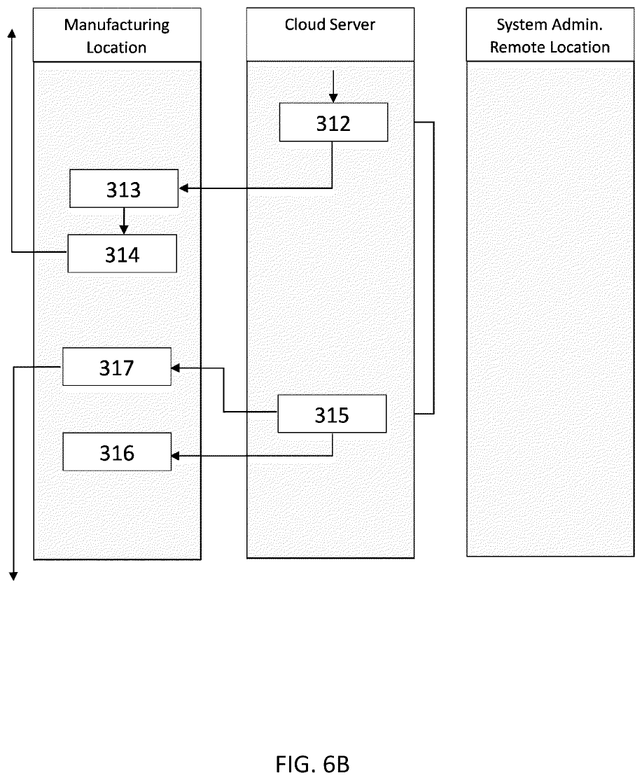

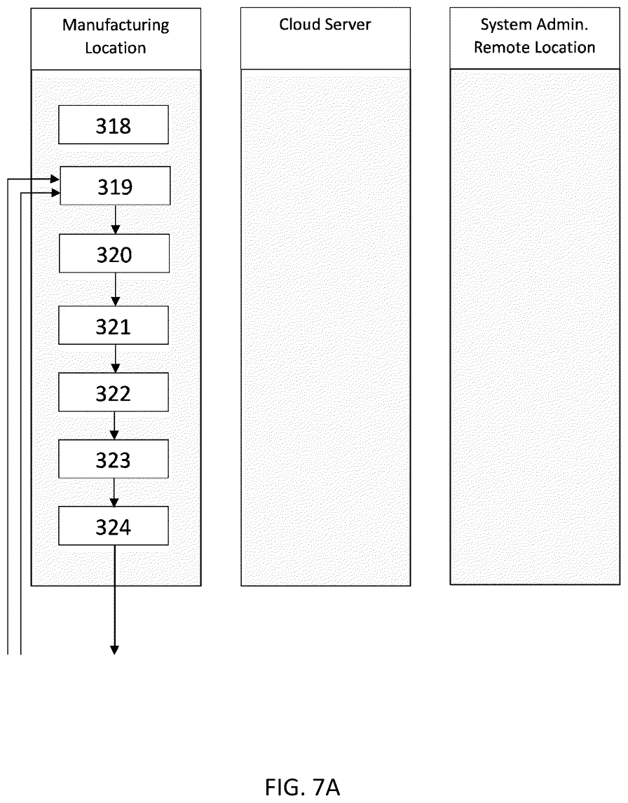

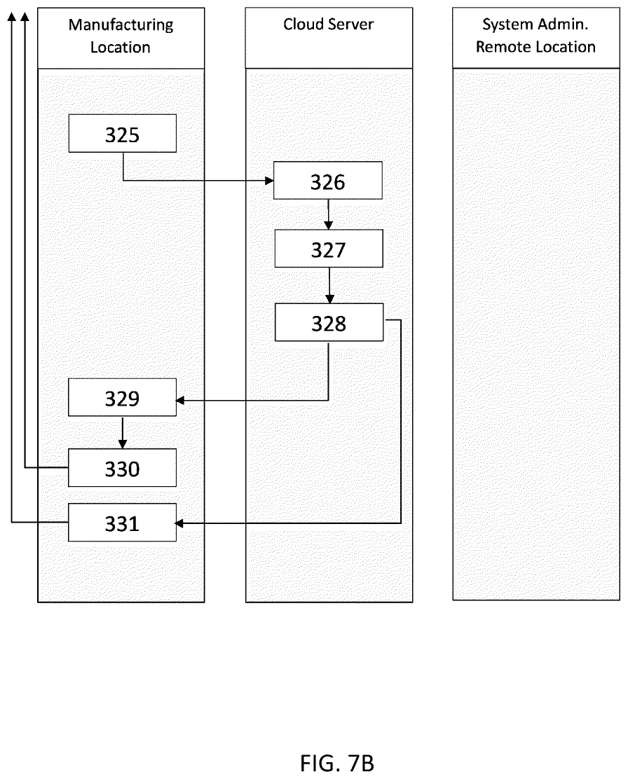

FIGS. 6A, 6B, 7A and 7B show a flow chart of an exemplary embodiment of the system 10 being used to generate data to calibrate optical coating apparatuses 12. The server 16 implements software for a single layer adjustment 301 and a multilayer adjustment 318 that is referred to as an Optical Coating Auto Tuner (OCAT). In step 302, the OCAT is ready for use. As mentioned above, the server 16 is configured to receive spectral front and or back measurements of a single layer or multilayer configuration, performed in an optical prescription laboratory, of either Rx prescription or mass manufacturing orientation, during production as an input. Examples described herein use a configured database in a distributed computing server system 102 103 to calculate or generate through the use of algorithms, the correction factors to be applied to the optical coating apparatuses 12 for future production runs 303. The described system allows for the optimization of the single and multilayer production runs in real time, therefore improving yield performance of the production runs.

The test optical coating is measured 304 for single layer/s 301 adjustment, by the operator/user, using an optical coating apparatus 107. The test optical coating is referred to as a sample in respect of the Figures. The layer material of the sample can consist of but is not limited to Cr₂O₃, SiO₂, ZrO₂, ZrO, Ti₃O₅, TiO₂, Al₂O₃, MgF₂, ZnO, ZnS, MgO, Ta₂O₅, HfO₂, Nb₂O₅, Indium Tin Oxide as well as mixtures of these materials and/or hyper- or sub-stoichiometric variations of these materials.

The sample is prepared for measurement using a spectrophotometer, or similar device, that is capable of, but not limited to measurements of 280 nanometres to 1100 nanometres for ultraviolet, visible and infrared light, and the operator/user measures the sample on the spectrophotometer or similar device 305. The user accesses the server implementing the OCAT, via a local computer, such as a computer/tablet or similar device, with host web portal connectivity 306, and selects the optical coating apparatus 107 that the sample was produced on in step 307. The user then selects the corresponding single layer reference file for the respective single layer material 308. The server populates the user interface fields with the information for that specific optical coating apparatus 107, such as, but not limited to tooling factor values, refractive index values for the material in step 309.

The user then uploads the coating data file including a wavelength data file in step 310, in the form of, but not limited to *.txt, *.csv, *.xls, *.xlsx file to the server. The user selects calculate result in step 311, and the server compares results of the measured spectral data to the specific requirements for that single layer material created as above as target specification data. The result is either a pass or fail which is reported to the user as a pass/fail message in step 312. If the returned result is a non-compliance, or a failure to meet requirements and limits provided, the server returns correction factors in step 313 in the form of a tooling factor value for the respective material layer being assessed. This tooling factor value is uploaded to the optical coating apparatus107 by the user in step 314.

The user then repeats the single layer sample production using the optical coating apparatus 107, and the measured spectral data of the optical coating applied by the adjusted optical coating apparatus 107 is compared against the target specification data to calculate whether this further sample passes the specific requirements for the single layer material. If the returned result is satisfactory, the single layer material result is compared to the requirements and limits provided by the server for the refractive index in step 315. If the returned result is a non-compliance or a failure to meet requirements, the server returns a message and detail of next level technical support in step 316. If the returned result is satisfactory for refractive index, the server reports an approval for production of multilayer thin film coating, or multilayer assessment 317, on the respective optical coating apparatus 107.

For the multilayer analysis, the multilayer sample/s are measured for multilayer adjustment in step 318. The operator/user produces the samples in step 319 using the optical coating apparatus 107. The multilayer sample can consist of but is not limited to Cr₂O₃, SiO₂, ZrO₂, ZrO, Ti₃O₅, TiO₂, Al₂O₃, MgF₂, ZnO, ZnS, MgO, Ta₂O₅, HfO₂, Nb₂O₅, Indium Tin Oxide as well as mixtures of these materials and/or hyper- or sub-stoichiometric variations of these materials, being in a plurality of alternating low and high refractive index materials. As above, the sample is prepared for measurement using a spectrophotometer or a similar device that is capable of, but not limited to measurements of 280 nanometres to 1100 nanometres for ultraviolet, visible and infrared light.

The user measures the sample on the spectrophotometer or similar device in step 320. The user accesses the server in step 321 as above and selects the optical coating apparatus107 that the sample was produced on in step 322. The user selects the corresponding multilayer reference file for the respective multilayer coating in step 323. The user selects the corresponding surface or side of the optical substrate (e.g., lens) treated with the respective multilayer coating 324. The server populates the user interface fields, as above, with the information, in step 325, for that specific optical coating apparatus 107, such as, but not limited to thickness values, refractive index values, color target values for the multilayer coating.

The user then uploads the coating data file including a wavelength data file 326 in the form of, but not limited to *.txt, *.csv, *.xls, *.xlsx file to the server. The user selects calculate in step 327, and the server calculates the result of the respective multilayer coating and compares results to the target specification data providing the specific requirements for that multilayer coating. The server then provides a pass/fail message in step 328 based on the comparison. If the returned result is a non-compliance or a failure to meet requirements and limits provided, the server returns correction factors in the form of new adjusted layer thickness values for the respective multilayer coating being assessed in step 329, which is uploaded to the optical coating apparatus 107 by the user in step 330. The server may further send to the first location the indication of a possible failure of the coating apparatus, if the server determined a possible failure of the coating apparatus based on information contained in the coating data file. Alternatively or additionally, the server may send to the first location a pass/fail message regarding the measured spectral data meeting the target specification data.

As above, the user then repeats the multilayer sample production, in steps 318 and 319, using the optical coating apparatus 107. If the returned further result is satisfactory for the multilayer rest reflex color, there is no change necessary, as noted in step 331, to the existing layer thickness of the respective thin film coating in the respective optical coating apparatus 107. Production therefore continues with the user producing a multilayer test sample in step 319 using the respective optical coating apparatus107.

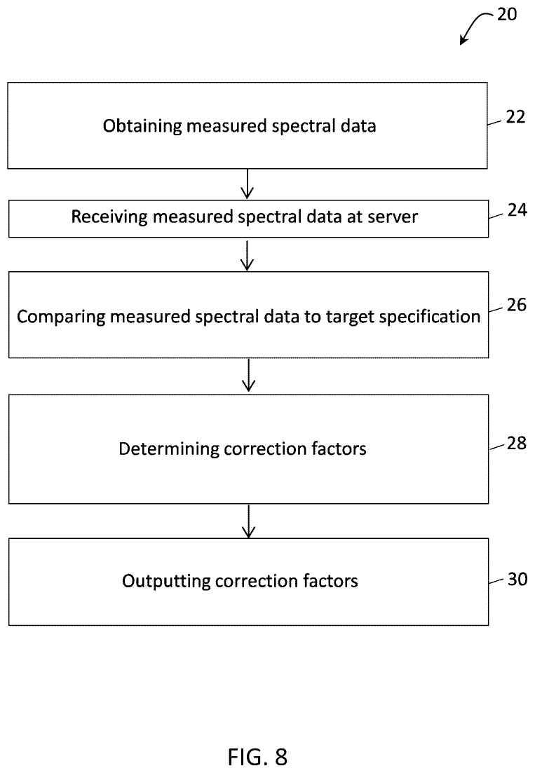

FIG. 8 shows a summary of a computer-implemented method 20 of generating data for calibrating optical coating apparatuses configured to apply optical coatings to surfaces of substrates, the method 20 including: obtaining 22 measured spectral data, from a measurement apparatus, of a test optical coating applied by an optical coating apparatus to a surface of a substrate and receiving 24 the measured spectral data at a server. The method 20 further includes: comparing 26 the measured spectral data to target specification data for the test optical coating for the optical coating apparatus; determining 28 correction factors for correcting deviations to the target specification data for the optical coating apparatus based on the comparison of the measured spectral data and the target specification data; and outputting 30, i.e. sending, the correction factors for the optical coating apparatus to adjust operation parameters of the optical coating apparatus to correct for the deviations to the target specification data.

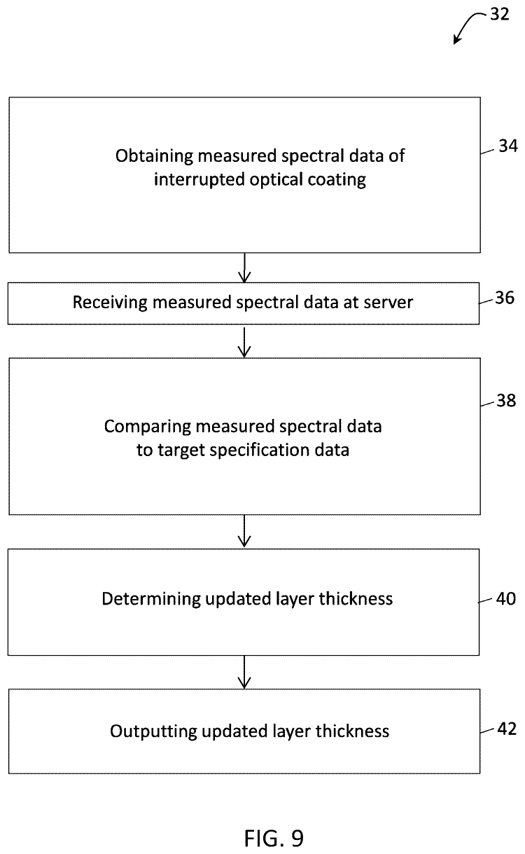

FIG. 9 shows a summary of a computer-implemented method 32 of recovering operation of optical coating apparatuses configured to apply optical coatings having a plurality of layers to surfaces of substrates, the method 32 including: obtaining 34 measured spectral data of an interrupted optical coating comprising one or more deposited layers, including an interrupted layer, applied by an optical coating apparatus from a measurement apparatus configured to measure spectral data of the interrupted optical coating and receiving 36 the measured spectral data at a server. The method further includes: comparing 38 the measured spectral data of the interrupted optical coating, comprising the one or more deposited layers, including the interrupted layer, to target specification data for the equivalent layers without interruption of the optical coating for the optical coating apparatus; determining 40 determining an updated layer thickness for correcting the interrupted layer based on the comparison of the measured spectral data and the target specification data; and outputting 42 the updated layer thickness for the optical coating apparatus to adjust operation parameters to correct for thickness of the interrupted layer.

Further aspects of the above methods 20, 32 will be apparent from the above description of the system 10. Persons skilled in the art will appreciate that the methods could be embodied in program code, executed by one or more processors of the server 16, which could be supplied in a number of ways, for example on a computer readable medium, such as a disc or a memory, or as a data signal, such as by transmitting it from a server.

Where any or all of the terms “comprise,” “comprises,” “comprised” or “comprising” are used in this specification (including the claims) they are to be interpreted as specifying the presence of the stated features, integers, steps or components, but not precluding the presence of one or more other features, integers, steps or components.

Finally, it will be understood that there may be other variation and modifications to the configurations described here that are also within the scope of the present disclosure.

All publications, patents and patent applications cited in this specification are herein incorporated by reference, and for any and all purposes, as if each individual publication, patent or patent application were specifically and individually indicated to be incorporated by reference. In the case of inconsistencies, the present disclosure will prevail.

### LIST OF REFERENCE SIGNS

10, 19 System
12, 107, 405 Optical Coating Apparatus
14 Measurement Apparatus
16 Server
18 Internet
20 Method of Generating Data
22 Obtaining Measured Spectral Data
24, 36 Receiving Measured Spectral Data
26, 38 Comparing Measured Spectral Data
28 Determining Correction Factors
30, 210 Outputting Correction Factors
32 Method of Recovering Operation
34 Obtaining Measured Spectral Data of Interrupted Coating
40 Determining Updated Layer Thickness
42 Outputting Updated Layer Thickness
100 Expert
101, 401 Expert Support Function
102 System Administration Server
103 Cloud Server
104 Local Computing Device
105 Measurement Device
106, 404 Operator
201 Single Layer Target File
202 Coating Design Target File
203 Substrate File
204 Thin Film Optical Coating Color Target Value
205 Single Layer Reference File
206 Setting up for Multilayer Reference File
207 Generating Multilayer Reference File
208 Transmitting Single and Multilayer Reference Files
209 Configuring Single Layer and Multilayer Adjustment
301 Single Layer Adjustment
302 OCAT Ready for Use
303 Future Production Run
304 Measuring Test Optical Coating
305 Measuring on Measurement Device
306 Host Web Portal Connectivity
307 Producing Sample
308 Selecting Single Layer Reference File
309, 325 Populating User Interface
310 Uploading Coating Data File
311 Calculating Results
312, 328 Reporting Pass/Fail
313 Returning Correction Factor
314 Uploading Correction Factor
315 Comparing Result to Requirement
316 Returning Message
317 Reporting Approval
318 Multilayer Adjustment
319 Producing Sample
320 Measuring Sample
321 Accessing Server
322 Selecting Optical Coating Apparatus
323 Selecting Multilayer Reference File
324 Selecting Surface
326 Uploading Coating Data File
327 Calculating and Comparing Multilayer Coating
329 Assessing Correction Factors
330 Uploading Assessed Correction Factors
331 Leaving Layer Thickness Unchanged
401 Expert Support Function
402 Local Computer
403 Spectrometer
406 Calibration
407 Applying Optical Coatings
408, 428 Applying Single Layer Test Optical Coating
409 Measuring Test Optical Coating
410 Software
411 Selecting Single Layer Reference File
412, 434 Browsing to Desired Wavelength Data File
413, 435 Importing Desired Wavelength Data File
414 Selecting Layer Target File
415, 437 Selecting Layer Material File
416, 438 Selecting Substrate Material File
417 Opening Layer Characterisation Set Up Parameters
418 Inputting Physical Thickness Upper and Lower Limits
419 Inputting Refractive Index Upper and Lower Limits
420 Selecting Refractive Index Dispersion Setting
421 Selecting Extinction Setting
422 Calculating Result
423, 443 Determining Pass/Fail
424 Defining Correction Factors
425 Updating Coating Apparatus
426 Defining Further Correction Factors
427 Updating Coating Apparatus with Further Correction Factors
429 Proceeding to Multilayer Adjustment
430 Applying Multilayer Test Optical Coating
431 Measuring Multilayer Test Optical Coating
432 Opening Software on Local Computer
433 Selecting Multilayer Reference File
436 Selecting Design Target File
439 Opening Coating Design Layer and Thickness Information
440 Selecting Layer or Layers to be Included
441 Determining an Allowed Change in Percent
442 Calculating Result Based on Selection
444 Running Production Coating Cycle
445 Removing Substrate
446 Measuring Applied Coating
447 Determining Whether Coating is Within Specification

1. A computer-implemented method of generating data for calibrating multiple optical coating apparatuses, each apparatus being located at a first location being one of several manufacturing locations and configured to apply an optical coating to a surface of a substrate, the method being carried out at a second location being a server at a system administration remote location, the method comprising:
receiving, at the second location, a coating data file from a local computer at the first location, the coating data file containing measured spectral data of a test optical coating having one or more coating layers applied by an optical coating apparatus at the first location, the measured spectral data being obtained from a measurement apparatus at the first location, wherein the measurement apparatus is in data communication with the local computer at the first location which is in data communication with the server at the second location via the Internet;
comparing, at the second location, the measured spectral data of the test optical coating applied by the optical coating apparatus to target specification data for the test optical coating for the optical coating apparatus;
determining, at the second location, correction factors for correcting deviations from the target specification data for the optical coating apparatus based on the comparison of the measured spectral data and the target specification data; and
sending a target data file containing the correction factors from the second location to the first location to calibrate the optical coating apparatus by adjusting at least one operation parameter of the optical coating apparatus based on the correction factors to correct for the deviations from the target specification data.

2. The computer-implemented method as claimed in claim 1, further comprising:
receiving the coating data file including the measured spectral data and data pertaining to the test optical coating and the optical coating apparatus at the second location; and
determining the correction factors based on the coating data file and the target specification data at the second location.

3. The computer-implemented method as claimed in claim 2, wherein data pertaining to the optical coating apparatus includes identification data of the optical coating apparatus.

4. The computer-implemented method as claimed in claim 2, wherein the test optical coating has one or more layers, and the data pertaining to the test optical coating includes layer data of the one or more layers of the test optical coating from the optical coating apparatus.

5. The computer-implemented method as claimed in claim 4, wherein the layer data includes layer material data of each of the one or more layers.

6. The computer-implemented method as claimed in claim 2, wherein the data pertaining to the test optical coating further includes surface data of the surface having the test optical coating from the optical coating apparatus.

7. The computer-implemented method as claimed in claim 2, wherein the data pertaining to the test optical coating further includes substrate data of the substrate of the surface having the test optical coating from the optical coating apparatus.

8. The computer-implemented method as claimed in claim 6, further comprising:
generating the target specification data for the test optical coating for the optical coating apparatus based on the received identification data, layer data, surface data and substrate data.

9. The computer-implemented method as claimed in claim 8, further comprising:
generating the target specification data from target files, wherein the target files include data pertaining to each of the optical coating apparatuses, a plurality of optical coating designs to be applied to a plurality of substrates by the optical coating apparatuses.

10. The computer-implemented method as claimed in claim 9, wherein the data pertaining to the optical coating apparatuses includes tooling factor values of the optical coating apparatus.

11. The computer-implemented method as claimed in claim 9, wherein the data pertaining to the plurality of optical coating designs includes layer material, refractive index values of the layer material of each the one or more layers, and layer thickness data of each the one or more layers.

12. The computer-implemented method as claimed in claim 1, wherein the target specification data includes spectral characteristics of the test optical coating.

13. The computer-implemented method as claimed in claim 1, further comprising:
recording the coating data file in association with corresponding correction factors.

14. The computer-implemented method as claimed in claim 13, further comprising:
determining causes for the deviations to the target specification data for the optical coating apparatus based on analysis of the recorded coating data file in association with corresponding correction factors.

15. The computer-implemented method as claimed in claim 14, further comprising:
receiving and recording operating conditions data of the optical coating apparatus when applying the test optical coating; and
further determining causes for the deviations to the target specification data for the optical coating apparatus based on analysis of the operating conditions data.

16. The computer-implemented method as claimed in claim 1, further comprising:
determining a warning when deviations to the target specification data for the optical coating apparatus are detected based on the comparison of the measured spectral data and the target specification data at the second location; and
sending the warning to the first location.

17. The computer-implemented method as claimed in claim 1, further comprising:
receiving the measured spectral data at a server at the second location, wherein the server is configured for implementing the steps of:
comparing the measured spectral data to target specification data for the test optical coating for the optical coating apparatus; and
determining correction factors for correcting deviations from the target specification data for the optical coating apparatus based on the comparison of the measured spectral data and the target specification data.

18. The computer-implemented method of claim 17, wherein the server is further configured for implementing the step of sending the target data file containing the correction factors to the first location.

19. The computer-implemented method as claimed in claim 1, wherein the target specification data includes Cauchy formula coefficients for materials of both low and high indices of refraction.

20. A server configured for generating data for calibrating multiple optical coating apparatuses, each apparatus being located at a first location being one of several manufacturing locations and configured to apply an optical coating to a surface of a substrate, the method being carried out at a second location being a server at a system administration remote location and configured to:
receive from a local computer at the first location a coating data file containing measured spectral data of a test optical coating applied by an optical coating apparatus from a measurement apparatus located at the first location and configured to measure spectral data of the test optical coating, wherein the measurement apparatus is in data communication with the local computer at the first location which is in data communication with the server at the server location via the Internet;
compare, at the server location, the measured spectral data to target specification data for the test optical coating for the optical coating apparatus;
determine correction factors for correcting deviations to the target specification data for the optical coating apparatus based on the comparison of the measured spectral data and the target specification data; and
send the correction factors from the server location to the optical coating apparatus at the first location to calibrate the optical coating apparatus by adjusting at least one operation parameter of the optical coating apparatus based on the correction factors to correct for the deviations to the target specification data.

21. A computer-implemented method of recovering operation of multiple optical coating apparatuses, each apparatus being located at a first location being one of several manufacturing locations and configured to apply optical coatings having a plurality of layers to surfaces of substrates, the method being carried out at a second location being a server at a system administration remote location, the method comprising:
receiving at the second location from a local computer at the first location a coating data file containing measured spectral data of an interrupted optical coating comprising one or more deposited layers, including an interrupted layer, obtained from a measurement apparatus located at the first location, wherein the measurement apparatus is in data communication with the local computer at the first location which is in data communication with the server at the second location via the Internet;
comparing, at the second location, the received measured spectral data to target specification data for the equivalent layers without interruption of the optical coating for the optical coating apparatus;
determining, at the second location, an updated layer thickness for correcting the interrupted layer based on the comparison of the measured spectral data and the target specification data; and
sending the updated layer thickness for the optical coating apparatus from the second location to the first location to adjust operation parameters to correct for thickness of the interrupted layer.

22. The computer-implemented method as claimed in claim 21, further comprising:
receiving the measured spectral data at a server at the second location, wherein the server is configured for implementing the steps of:
comparing measured spectral data of an interrupted optical coating comprising one or more deposited layers, including an interrupted layer, to target specification data for the equivalent layers without interruption of the optical coating for the optical coating apparatus; and
determining an updated layer thickness for correcting the interrupted layer based on the comparison of the measured spectral data and the target specification data.

23. The computer-implemented method as claimed in claim 22, wherein the server is further configured for implementing the step of sending the updated layer thickness to the first location.

24. A server configured for recovering operation of optical coating apparatuses, each apparatus being located at a first location being one of several manufacturing locations and configured to apply optical coatings having a plurality of layers to surfaces of substrates, wherein the server is located at a server location being a system administration remote location and configured to:
receive from a local computer at the first location a coating data file containing measured spectral data of an interrupted optical coating comprising one or more deposited layers, including an interrupted layer, applied by an optical coating apparatus from a measurement apparatus, the measurement apparatus being located at the first location and configured to measure spectral data of the interrupted optical coating, wherein the measurement apparatus is in data communication with the local computer at the first location which is in data communication with the server at the server location via the Internet;
compare, at the server location, the measured spectral data of the deposited layers, including the interrupted layer, to target specification data for the equivalent layers without interruption of the optical coating for the optical coating apparatus;
determine, at the server location, an updated layer thickness for correcting the interrupted layer based on the comparison of the measured spectral data and the target specification data; and
send the updated layer thickness for the optical coating apparatus from the server location to the first location to adjust operation parameters to correct for thickness of the interrupted layer.

25. A method for manufacturing a spectacle lens based on at least one of the coated substrates, wherein the method includes the method as claimed in claim 1.

26. A computer program comprising instructions which, when the program is executed by a computer, cause the computer to carry out the method as claimed in claim 1.

27. A non-transitory computer-readable storage medium comprising instructions which, when executed by a computer, cause the computer to carry out the method as claimed in claim 1.

28. An optical coating system comprising an optical coating apparatus and a local computer located at a first location being a manufacturing location remote from a server at a second location being a system administration remote location, wherein the optical coating system is configured to implement a calibration of the optical coating apparatus based on data for calibrating the optical coating apparatus received from the server at the second location, the optical coating system comprising:
a memory storing instructions; and
at least one processor configured to execute instructions to:
apply, by the optical coating apparatus, a test optical coating to surfaces of substrates at the first location based on target specification data;
measure, by a measurement apparatus, spectral data of the test optical coating applied by the optical coating apparatus; and
send, by the local computer of the optical coating system at the first location, the spectral data of the test optical coating to the server at the second location for calculating correction factors to correct for the deviations to the target specification data for the optical coating apparatus.

29. The optical coating system as claimed in claim 28, wherein the at least one processor is further configured to:
receive, by a local computer of the optical coating system at the first location, the correction factors from the server at the second location;
based on the correction factors, adjust, by a local computer of the optical coating system at the first location, operation parameters of the optical coating apparatus to correct for the deviations to a target specification data.

30. A computer-implemented method of calibrating an optical coating apparatus located at a first location being one of several manufacturing locations, wherein the optical coating apparatus is configured to apply an optical coating to a surface of a substrate, the method comprising:
obtaining from a measurement apparatus at the first location measured spectral data of a test optical coating having one or more coating layers applied by the optical coating apparatus, wherein the measurement apparatus is in data communication with a local computer at the first location;
sending a coating data file containing the spectral data from a local computer at the first location to a server at the second location, the second location being a system administration remote location, wherein the local computer at the first location is in data communication with the server at the second location via the Internet; and
receiving at the local computer at the first location from the server at the second location a target data file containing the correction factors and calibrating the optical coating apparatus by adjusting at least one operation parameter of the optical coating apparatus based on the correction factors to correct for the deviations to the target specification data.

31. A computer-implemented method of recovering operation of an optical coating apparatus located at a first location being one of several manufacturing locations and being configured to apply an optical coating having a plurality of layers to a surface of a substrate, the method comprising:
obtaining from a measurement apparatus at the first location measured spectral data of an interrupted optical coating comprising one or more deposited layers, including an interrupted layer, wherein the measurement apparatus is in data communication with a local computer at the first location;
sending the received measured spectral data from the local computer at the first location to a server at the second location, the second location being a system administration remote location, wherein the local computer at the first location is in data communication with the server at the second location via the Internet; and
receiving at the local computer at the first location from the server at the second location an updated layer thickness for the optical coating apparatus to adjust operation parameters to correct for thickness of the interrupted layer.
